(19) United States
(12) Patent Application Publication
(10) Pub. No.: US 2024/0386153 A1
(43) Pub. Date: Nov. 21, 2024

(54) System and Method for Generating Automated Anchor Rod Drawings

(71) Applicant: Cornerstone Building Brands, Inc., Cary, NC (US)

(72) Inventors: Trevor C. Cornelsen, Knoxville, TN (US); Vinay J. Thottunkal, Norman, OK (US); Michael A. Dubayeh, Houston, TX (US)

(73) Assignee: Cornerstone Building Brands, Inc., Cary, NC (US)

(21) Appl. No.: 18/667,413

(22) Filed: May 17, 2024

Related U.S. Application Data
(60) Provisional application No. 63/503,252, filed on May 19, 2023.

(51) Int. Cl. G06F 30/13

(52) U.S. Cl. CPC G06F 30/13

(57) ABSTRACT

A computing system receives an anchor rod drawing request from a user device, the anchor rod drawing request that includes parameters associated with a target structure. The computing system determines whether the anchor rod drawing request is compatible with an automated anchor rod drawing process. The computing system generates design information for an anchor rod system based on the anchor rod drawing request. The computing system generates preliminary anchor rod drawings based on the design information using a computer aided design program. The computing system prompts a sealing engineer to review and approve the preliminary anchor rod drawings. The computing system receives an indication that the sealing engineer has reviewed and approved the preliminary anchor rod drawings. Responsive to the indication, the computing system generates permit drawings based on one or more of the approved anchor rod drawings and/or the parameters.

### CROSS REFERENCE TO RELATED APPLICATIONS

This application claims priority to U.S. Provisional Application Ser. No. 63/503,252, filed May 19, 2023, which is hereby incorporated by reference in its entirety.

### FIELD OF DISCLOSURE

Embodiments disclosed herein generally relate to systems and methods for generating automated anchor rod drawings and/or permit drawings for a proposed structure.

### BACKGROUND

Anchor rod drawings may be used by contractors or engineers for determining where to install and place anchor rods within a proposed structure. The typical process for generating anchor rod drawings can be a time consuming process during which a sealing engineer or structural engineer must design the anchor rod system, generate drawing representing the design of the anchor rod system, and seek approval of the anchor rod drawings to ensure that they satisfy the various requirements of the project, as well as being in compliance with local building codes.

### SUMMARY

In some embodiments, a method of generating anchor rod drawings for a building project is disclosed herein. A computing system receives an anchor rod drawing request from a user device. The anchor rod drawing request includes parameters associated with a target structure. The computing system determines whether the anchor rod drawing request is compatible with an automated anchor rod drawing process by comparing the parameters associated with the target structure to pre-established conditions. The pre-established conditions define a suitability of the anchor rod drawing request with the automated anchor rod drawing process. Based on determining that the anchor rod drawing request is compatible with the automated anchor rod drawing process, the computing system generates design information for an anchor rod system based on the anchor rod drawing request by applying one or more of applicable building codes, structural engineering principles, steel construction specifications, or metal building specifications to the parameters associated with the target structure. The computing system generates preliminary anchor rod drawings based on the design information using a computer aided design program. The computing system prompts a sealing engineer to review and approve the preliminary anchor rod drawings. The computing system receives an indication that the sealing engineer has reviewed and approved the preliminary anchor rod drawings. Responsive to the indication, the computing system generates permit drawings based on one or more of the approved anchor rod drawings and/or the parameters. The computing system delivers approved anchor rod drawings and the permit drawings to the user device.

In some embodiments, a system is disclosed herein. The system includes a processor and a memory. The memory has programming instructions stored thereon, which, when executed by the processor, causes the system to perform operations. The operations include receiving an anchor rod drawing request from a user device, the anchor rod drawing request comprising parameters associated with a target structure. The operations further include determining whether the anchor rod drawing request is compatible with an automated anchor rod drawing process by comparing the parameters associated with the target structure to pre-established conditions. The pre-established conditions define a suitability of the anchor rod drawing request with the automated anchor rod drawing process. The operations further include, based on determining that the anchor rod drawing request is compatible with the automated anchor rod drawing process, generating design information for an anchor rod system based on the anchor rod drawing request by applying one or more of applicable building codes, structural engineering principles, steel construction specifications, or metal building specifications to the parameters associated with the target structure. The operations further include generating preliminary anchor rod drawings based on the design information using a computer aided design program. The operations further include prompting a sealing engineer to review and approve the preliminary anchor rod drawings. The operations further include receiving an indication that the sealing engineer has reviewed and approved the preliminary anchor rod drawings. The operations further include, responsive to the indication, generating permit drawings based on one or more of the approved anchor rod drawings and/or the parameters. The operations further include delivering approved anchor rod drawings and the permit drawings to the user device.

In some embodiments, a non-transitory computer readable medium is disclosed herein. The non-transitory computer readable medium includes one or more sequences of instructions, which, when executed by one or more processors, causes a computing system to perform operations. The operations include receiving, by the computing system, an anchor rod drawing request from a user device, the anchor rod drawing request comprising parameters associated with a target structure. The operations further include determining, by the computing system, whether the anchor rod drawing request is compatible with an automated anchor rod drawing process by comparing the parameters associated with the target structure to pre-established conditions. The pre-established conditions define a suitability of the anchor rod drawing request with the automated anchor rod drawing process. The operations further include, based on determining that the anchor rod drawing request is compatible with the automated anchor rod drawing process, generating, by the computing system, design information for an anchor rod system based on the anchor rod drawing request by applying one or more of applicable building codes, structural engineering principles, steel construction specifications, or metal building specifications to the parameters associated with the target structure. The operations further include generating, by the computing system, preliminary anchor rod drawings based on the design information using a computer aided design program. The operations further include prompting, by the computing system, a sealing engineer to review and approve the preliminary anchor rod drawings. The operations further include receiving, by the computing system, an indication that the scaling engineer has reviewed and approved the preliminary anchor rod drawings. The operations further include, responsive to the indication, generating, by the computing system, permit drawings based on one or more of the approved anchor rod drawings and/or the parameters. The operations further include delivering, by the computing system, approved anchor rod drawings and the permit drawings to the user device.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a block diagram illustrating a computing environment, according to example embodiments.

FIG. 1B is a block diagram illustrating a computing environment, according to example embodiments.

FIG. 2 is a block diagram illustrating exemplary workflows within Design environment, according to example embodiments.

FIG. 3 is a flow diagram illustrating a method of automatically generating anchor rod drawings, according to example embodiments.

FIG. 4 illustrates a conventional anchor rod drawing, according to example embodiments.

FIG. 5A illustrates an improved anchor rod drawing, according to example embodiments.

FIG. 5B illustrates an improved permit drawing, according to example embodiments.

FIG. 6 illustrates an exemplary graphical user interface (GUI), according to example embodiments.

FIG. 7A illustrates a system bus computing system architecture, according to example embodiments.

FIG. 7B illustrates a computer system having a chipset architecture, according to example embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments disclosed herein generally relate to a system and method of automatically generating anchor rod drawings for a project based on inputs from a user or customer. As those skilled in the art understand, the conventional process for generating anchor rod drawings for a project is a time consuming task that may require constant feedback interaction with a customer or user requesting the anchor rod drawings. Currently, anchor rod drawings that may be generated for users are preliminary in nature, in that they are intended to merely assist users as they set up their building configuration, as well as provide an aid for foundation pricing. The current state of anchor rod drawings is insufficient for allowing a contractor, for example, to build and pour the foundation of a structure due to the quality of the drawings, as well as the limited information provided in these preliminary drawings.

One or more techniques provided herein improve upon conventional processes by providing a fully automated anchor rod drawing workflow for certain projects that satisfy a threshold level of conditions (e.g., those projects that are of lower complexity). Such workflow reduces the lead time for signed/scaled anchor rod drawings from as long as two to three weeks to within three days of purchase. In some embodiments, in addition to generating anchor rod drawings, one or more techniques described herein may also generate permit drawings. Such permit drawings may be used as a submission to a local government or regulatory agency in order to obtain the necessary construction permits before a construction project.

The term “user” as used herein includes, for example, a person or entity that owns a computing device or wireless device; a person or entity that operates or utilizes a computing device; or a person or entity that is otherwise associated with a computing device or wireless device. It is contemplated that the term “user” is not intended to be limiting and may include various examples beyond those described. The term “user” may be used to reference a customer seeking anchor rod drawings.

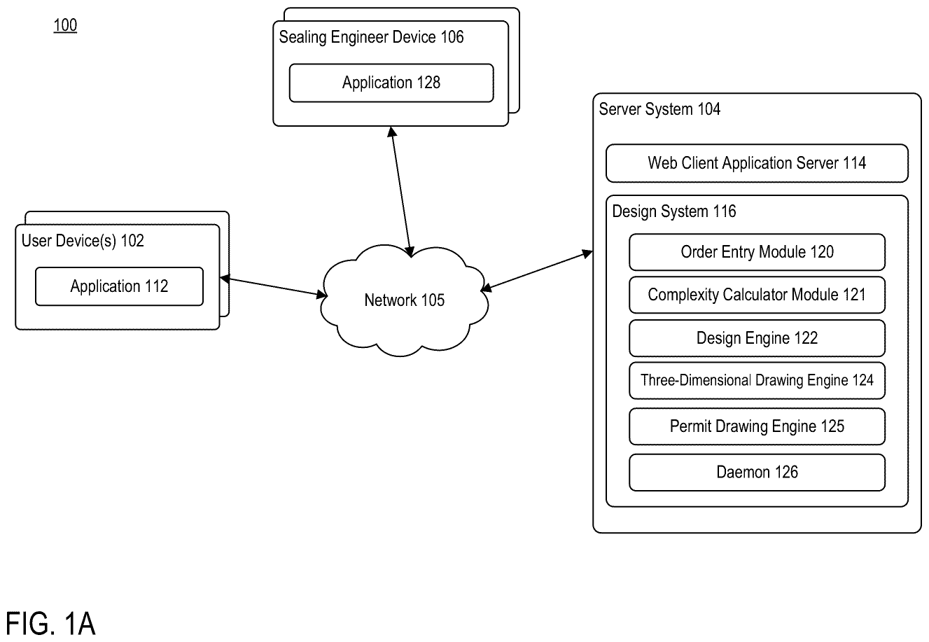

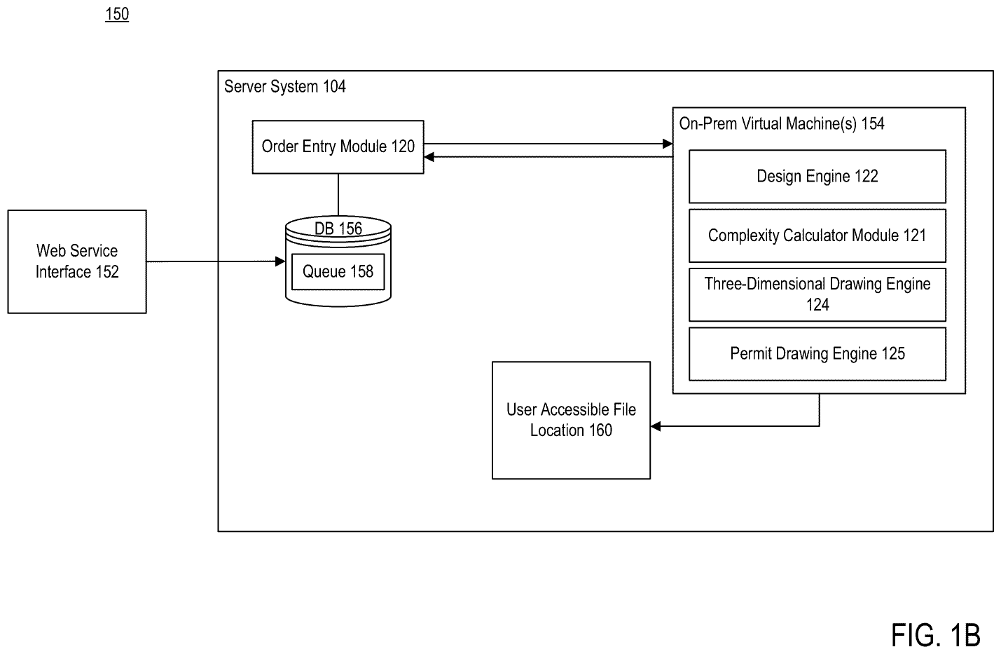

FIG. 1A is a block diagram illustrating a computing environment 100, according to one embodiment. Computing environment 100 may include at least a user device 102, a server system 104, and sealing engineer device 106 communicating via network 105.

Network 105 may be representative of any suitable type, including individual connections via the Internet, such as cellular or Wi-Fi networks. In some embodiments, network 105 may connect terminals, services, and mobile devices using direct connections, such as radio frequency identification (RFID), near-field communication (NFC), Bluetooth™, low-energy Bluetooth™ (BLE), Wi-Fi™, ZigBee™, ambient backscatter communication (ABC) protocols, USB, WAN, or LAN. Because the information transmitted may be personal or confidential, security concerns may dictate one or more of these types of connection be encrypted or otherwise secured. In some embodiments, however, the information being transmitted may be less personal, and therefore, the network connections may be selected for convenience over security.

Network 105 may include any type of computer networking arrangement used to exchange data. For example, network 105 may be representative of the Internet, a private data network, virtual private network using a public network and/or other suitable connection(s) that enables components in computing environment 100 to send and receive information between the components of computing environment 100.

User device 102 may be operated by a user. In some embodiments, user device 102 may be representative of one or more computing devices, such as, but not limited to, a mobile device, a tablet, a personal computer, a laptop, a desktop computer, or, more generally, any computing device or system having the capabilities described herein.

Application 112 may be representative of an application associated with server system 104. In some embodiments, application 112 may be a standalone application associated with server system 104. In some embodiments, application 112 may be representative of a web-browser configured to communicate with server system 104. In some embodiments, user device 102 may communicate over network 105 to request a webpage, for example, from web client application server 114 of server system 104. For example, user device 102 may be configured to execute application 112 to access functionality of design system 116 to generate designs for a target engineering project. The content that is displayed to user device 102 may be transmitted from web client application server 114 to user device 102 and subsequently processed by application 112 for display via a graphical user interface (GUI) of user device 102.

Sealing engineer device 106 may be operated by a sealing engineer. A sealing engineer may refer to an engineer that is trained or authorized to review and approve building plans generated by server system 104. As part of the review process, the sealing engineer may affix their seal of approval on the building plans as a means to authenticate the design. In some embodiments, sealing engineer device 106 may be representative of one or more computing devices, such as, but not limited to, a mobile device, a tablet, a personal computer, a laptop, a desktop computer, or, more generally, any computing device or system having the capabilities described herein.

Application 128 may be representative of an application associated with server system 104. In some embodiments, application 128 may be a standalone application associated with server system 104. In some embodiments, application 128 may be representative of a web-browser configured to communicate with server system 104. In some embodiments, sealing engineer device 106 may communicate over network 105 to request a webpage, for example, from web client application server 114 of server system 104. For example, sealing engineer device 106 may be configured to execute application 128 to access functionality of design system 116 to access and review designs that were generated for a target engineering project. The content that is displayed to sealing engineer device 106 may be transmitted from web client application server 114 to sealing engineer device 106 and subsequently processed by application 128 for display via a graphical user interface (GUI) of sealing engineer device 106.

Server system 104 may be configured to communicate with user devices 102 and scaling engineer devices 106. Server system 104 may be configured to host design system 116. Design system 116 may be representative of a workspace or computing environment in which users can upload requests for the generation of anchor rod drawings for a particular project.

As shown, design system 116 may include order entry module 120, complexity calculator module 121, design engine 122, three-dimensional drawing engine 124, and permit drawing engine 125. Each of order entry module 120, complexity calculator module 121, design engine 122, three-dimensional drawing engine 124, and permit drawing engine 125 may be comprised of one or more software modules. The one or more software modules are collections of code or instructions stored on a media (e.g., memory of server system 104) that represent a series of machine instructions (e.g., program code) that implements one or more algorithmic steps. Such machine instructions may be the actual computer code the processor of server system 104 interprets to implement the instructions or, alternatively, may be a higher level of coding of the instructions that are interpreted to obtain the actual computer code. The one or more software modules may also include one or more hardware components. One or more aspects of an example algorithm may be performed by the hardware components (e.g., circuitry) itself, rather than as a result of the instructions.

Order entry module 120 may be configured to interface with user device 102. Order entry module 120 may be configured to receive inputs from user device 102. Such inputs may be used by design engine 122 when designing an anchor rod system. In some embodiments, the inputs may include, but are not limited to, one or more of a target building geometry, jobsite specific environmental loads (e.g., live/wind, snow, seismic, and the like), governing building codes of the target location of the target building, and/or project specific building characteristics.

Complexity calculator module 121 may generate an estimated complexity of an order request based on the inputs received by order entry module 120. For example, in assessing whether a user's job request satisfies the conditions for the generation of anchor rod designs and/or permit drawings, order entry module 120 may submit an application programming interface (API) call to complexity calculator module 121. Complexity calculator module 121 may have a plurality of input fields for generating an estimated complexity of a given job request. In operation, the API call from order entry module 120 to complexity calculator module 121 may involve a translation from the raw inputs received from user device 102 to inputs compatible with complexity calculator module 121. In some embodiments, such process may also involve a mapping of inputs received from user device 102 to input fields of complexity calculator module 121 such that complexity calculator module 121 can automatically generate an estimated complexity for the proposed request. If the estimated complexity is above a threshold complexity, such request may be deemed not suitable for generation of anchor rod drawings. If, however, the estimate complexity is within the threshold complexity, then order entry module 120 may permit the request to continue.

Design engine 122 may be configured to receive inputs from order entry module 120 and generate an anchor rod system design based on the inputs. For example, design engine 122 may be configured to generate an anchor rod system design by applying one or more of applicable building codes, structural engineering principles, and steel construction and metal building specifications to the user's inputs. Based on this process, design engine 122 may generate manufacturing specifications to size each anchor rod in the anchor rod system, as well as create calculations for metal buildings. In some embodiments, design engine 122 may generate or develop initial framing and analytical models for the framing elements of the structure based on user inputs. Design engine 122 may then apply loads to the outer elements of the initial framing to establish size, spacing, and/or potential conflicts based on the user inputs. Such process may act as supports for the next level of framing elements. Design engine 122 may then perform analysis of members to establish loads to compare with capacities calculated as a function of interconnectivity of the different levels of framing elements. Design engine 122 may then optimize the building design from the outermost element level inward. Once all the building elements are optimized, design engine 122 may perform a final analysis that may generate the required support reactions at the base of columns to maintain structure equilibrium. In some embodiments, as output, design engine 122 may generate design information for the anchor rod system in the form of one or more of design reports, sketches, anchor rod sizes, base reactions (e.g., column reactions by which the building columns transmit force to the foundation), bills of materials, and/or design summaries.

Three-dimensional drawing engine 124 may be configured to generate anchor rod drawings based on output from design engine 122. In some embodiments, three-dimensional drawing engine 124 may be representative of one or more computer aided design software systems, such as, but not limited to, AutoCAD or TEKLA. In some embodiments, three-dimensional drawing engine 124 may generate three-dimensional drawings of the anchor rod design generated by design engine 122 based on, for example, the anchor rod sizes and base reactions.

In some embodiments, to generate the anchor rod drawings, three-dimensional drawing engine 124 may generate applied loads based on the input. In some embodiments, the applied loads that were generated may include environmental loads from applicable building codes. Exemplary environmental loads may include, but are not limited to, one or more of wind, snow, seismic, and/or rain. In some embodiments, the applied loads that were generated may include roof construction/maintenance live loads from applicable building code. In some embodiments, the applied loads that were generated may include auxiliary loads from rooftop units or cranes/hoists. In some embodiments the applied loads that were generated may include self-weight from permanent structures and other fixtures. Examples may include, but are not limited to, one or more of the weight of the roof and structural members, electrical, mechanical, plumbing, sprinklers, ceiling, and the like.

In some embodiments, three-dimensional drawing engine 124 may start by applying the loads that were generated to the outermost structural elements (e.g., framing members such as, but not limited to, panels, roof purlins, wall girts, endwall columns, and frames) of the design and following the structural load path down until the load makes it to the ground. For example, applied loads may flow from the roof/wall panel to the purlins/girts and then to the frame rafters/columns, end-wall columns, framed openings, and x-bracings. Such process may be performed using one or more techniques such as, but not limited to, tributary area, summation of forces, summation of moments, shear and moment diagrams, and/or stiffness calculations.

Based on the above processes, three-dimensional drawing engine 124 may generate the anchor rod drawings that include column base sizes, reactions, and anchor rod patterns for each column. Such drawings may be used by foundation engineers to design the building foundation. Such drawings may also be used by contractors for building and pouring the foundation.

The present approach provides an improvement over conventional processes. For example, through this approach, a user is able to take advantage of an automated anchor rod workflow, through which column base reaction schematics can be automatically generated with reduced or limited user input. Such functionality yields greater speed in the anchor rod design process.

Permit drawing engine 125 may be configured to generate permit drawings based on inputs from order entry module 120 and one or more of the output from design engine 122 or output from three-dimensional drawing engine 124. Such permit drawings may be used as a submission to a local government or regulatory agency in order to obtain the necessary construction permits before a construction project. In some embodiments, permit drawings may include, but are not limited to, one or more of site plans, floor plans, elevations, sections, or, more generally, an overall design intent of the structure to be constructed. Because these permit drawings are used for submission to a local government or regulatory agency, they typically must comply with local zoning laws, building codes, or other regulations. As such, permit drawing engine 125 may generate drawings that have the necessary level of detail for these parties to review and approve the construction project. In some embodiments, permit drawing engine 125 may generate permit drawings using Tekla.

Once the anchor rod drawings and/or permit drawings are generated, design system 116 may import the anchor rod drawings and/or permit drawings to the design file folder for review by a sealing engineer.

In some embodiments, server system 104 may further include daemon 126. Daemon 126 may be configured to execute one or more workflows within design system 116. For example, daemon 126 may be configured to coordinate processes among one or more of order entry module 120, design engine 122, and three-dimensional drawing engine 124.

FIG. 1B is a block diagram illustrating a computing environment 150, according to example embodiments. Computing environment 150 may focus on communication among components associated with server system 104. For example, as shown, computing environment 150 may include a web service interface 152 communicating with server system 104. Web service interface 152 may be representative of an interface that allows for communication between user device 102 and server system 104. In some embodiments, web service interface 152 may be representative of an example of application 112. Via web service interface 152, a user may submit an order request to server system 104. Web service interface 152 may add the order request to an order queue 158 stored in database 156 associated with server system 104. Order entry module 120 may monitor queue 158 to determine when new order requests are uploaded.

When order entry module 120 identifies a new order request, order entry module 120 may screen the new order request to determine whether the new order request is compatible with the automated anchor rod process. As shown, each of complexity calculator module 121, design engine 122, three-dimensional drawing engine 124, and permit drawing engine 125 execute across one or more on-premise virtual machines 154. In this manner, components of design system 116 may be scaled up or scaled down depending on user demand. Such modules may provide their outputs (e.g., anchor rod drawings and/or permit drawings) to a user accessible file location 160. Via user accessible file location 160 any of user device 102 or sealing engineer device 106 may review and analyze the outputs.

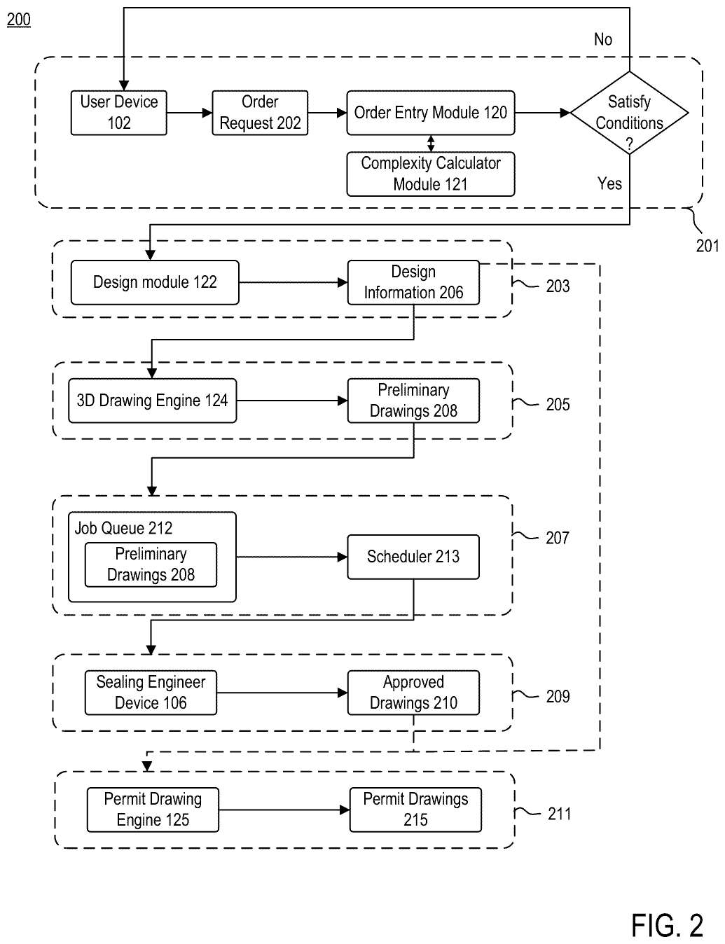

FIG. 2 is a block diagram 200 illustrating exemplary workflows within design system 116, according to example embodiments. As shown, a first workflow 201 may begin by user device 102 submitting an order request 202 to order entry module 120. Order request 202 may include inputs that may be representative of information relating to the project for which anchor rod drawings will be generated. In some embodiments, inputs may include, but are not limited to, one or more of building geometry, jobsite, specific environmental loads, governing building code, and project specific building characteristics.

Order entry module 120 may receive and compare inputs from order request 202 to a set of conditions stored in a network accessible database. In some embodiments, conditions may dictate whether a user can leverage a workflow for automatically generating anchor rod designs. In essence, order entry module 120 may use conditions as a filtering mechanism to determine whether a user can leverage the automated workflow for anchor rod designs or whether the user's order request is too complex for an automated anchor rod design workflow. In such embodiments, the user's order request may be more compatible with a conventional non-automated workflow for anchor rod designs.

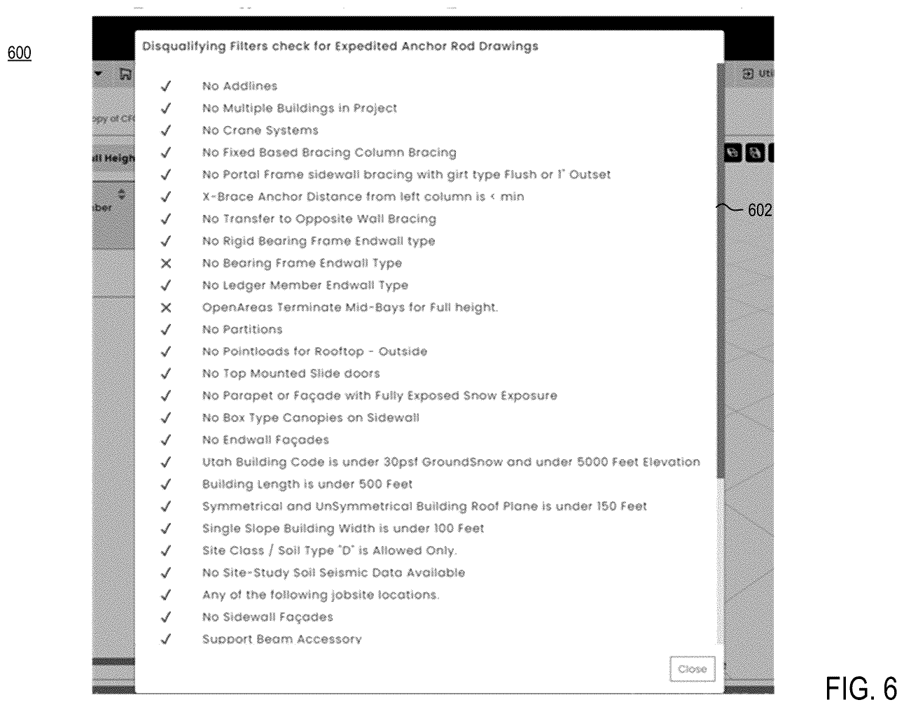

In some embodiments, the conditions (some of which are shown in FIG. 6 discussed below) may be representative of conditions that ensure the order request from user device 102 is not too complex for design engine 122 and three-dimensional drawing engine 124 to generate the anchor rod drawings automatically, with reduced human intervention. The conditions may dictate whether design engine 122 and three-dimensional drawing engine 124 can proceed with the anchor rod design process.

In some embodiments, an operator may review order request 202. For example, there may be a situation where the user submits notes along with their inputs in order request 202. Such notes may require a manual review to ensure that order request 202 is compatible with the automated anchor rod design process.

As shown, the comparison process may be iterative in nature. For example, if order request 202 does not satisfy the conditions, order entry module 120 may notify user device 102 that order request 202, in its current state, is not compatible with the automated anchor rod drawing workflow. In some embodiments, the notification may be in the form of a dashboard that includes the list of conditions used by order entry module 120 and an indication of whether the order entry satisfied each condition. In this manner, the user may be able to adjust the inputs of order request 202, such that the request is compatible with the automated anchor rod drawing design workflow.

In some embodiments, order entry module 120 may communicate with complexity calculator module 121 to determine whether the request satisfies the conditions for proceeding with the anchor rod design process. For example, in assessing whether a user's job request satisfies the conditions for the generation of anchor rod designs and/or permit drawings, order entry module 120 may submit an application programming interface (API) call to complexity calculator module 121 such that complexity calculator module 121 can generate an estimated complexity of order request 202. If the estimated complexity of order request 202 is within a threshold level complexity, then order entry module 120 may allow the process to proceed.

In some embodiments, once order entry module 120 accepts order request 202, daemon 126 may generate a design folder structure for order request 202. In some embodiments, daemon 126 may populate the design folder structure with information from order request 202. In some embodiments, the design folder structure may be accessible to user device 102. For example, via application 112, a user can view order request 202 in its design folder structure.

Order entry module 120 may trigger a second workflow 203 once order request 202 has been accepted. Second workflow 203 may begin when daemon 126 provides design engine 122 with order request 202. Based on order request 202, design engine 122 may generate design information 206. For example, as discussed above, design engine 122 may generate an anchor rod system design by applying one or more of applicable building codes, structural engineering principles, and steel construction and metal building specifications to the inputs of order request 202. In some embodiments, design information 206, generated by design engine 122, may include design reports, sketches, anchor rod sizes, base reactions bills of materials, design summaries, and the like for use by three-dimensional drawing engine 124.

In some embodiments, daemon 126 may populate design folder structure with design information 206, such that design information 206 may be accessible to user device 102 and/or sealing engineer device 106.

Design engine 122 may trigger a third workflow 205 once design information 206 has been generated. Third workflow 205 may begin when daemon 126 provides design information 206 to three-dimensional drawing engine 124. Based on design information 206, three-dimensional drawing engine 124 may generate preliminary anchor rod system drawings (“preliminary drawings”) 206.

As discussed above, three-dimensional drawing engine 124 may generate preliminary drawings 208 by applying applied loads to design information 206. In some embodiments, the applied loads may include environmental loads from applicable building codes, roof construction/maintenance live loads from applicable building codes, auxiliary loads from rooftop units or cranes/hoists. self-weight from permanent structures and other fixtures, and the like. Based on this process, three-dimensional drawing engine 124 may generate preliminary drawings 208 that include column base sizes, reactions, and anchor rod patterns for each column.

In some embodiments, daemon 126 may populate design folder structure with preliminary drawings 208, such that preliminary drawings 208 may be accessible to user device 102 and/or sealing engineer device 106.

Three-dimensional drawing engine 124 may trigger a fourth workflow 207 once preliminary drawings 208 have been generated. Fourth workflow 207 may begin when daemon moves preliminary drawings 208 to a job queue 212. In some embodiments, job queue 212 may be managed by a scheduler 213. Scheduler 213 may be configured to review the jobs (e.g., preliminary drawings 208) in job queue 212 and assign a job or preliminary drawing to a respective sealing engineer device 106 for review and approval.

Scheduler 213 may trigger a fifth workflow 209. Fifth workflow 209 may begin when scheduler 213 assigns sealing engineer device 106 preliminary drawings 208 for review and approval. A sealing engineer associated with sealing engineer device 106 may review preliminary drawings 208. Once sealing engineer approves preliminary drawings 208, sealing engineer device 106 may generate approved drawings 210. In some embodiments, approved drawings 210 may simply be representative of preliminary drawings 208 with the sealing engineer's seal of approval.

In some embodiments, daemon 126 may populate design folder structure with approved drawings 210, such that approved drawings 210 may be accessible to user device 102.

In this manner, daemon 126 may facilitate an automated process for generating anchor rod drawings.

In some embodiments, FIG. 2 may include a sixth workflow 211. During the sixth workflow, permit drawing engine 125 may generate permit drawings based on one or more of design information 206 or approved drawings 210. In some embodiments, sixth workflow may involve substantially similar steps in generating the permit drawings as involved in generating the anchor rod drawings. In some embodiments, permit drawing engine 125 may use Tekla to generate the permit drawings based on design information 206 and/or approved drawings 210. In some embodiments, daemon 126 may populate design folder structure with permit drawings 215, such that permit drawings 215 may be accessible to user device 102.

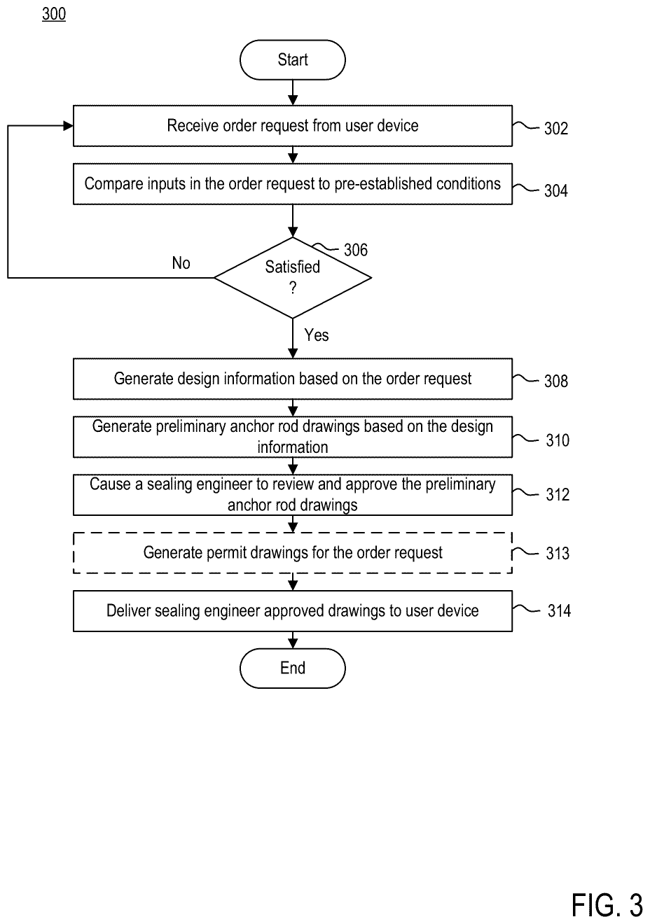

FIG. 3 is a flow diagram illustrating a method 300 of automatically generating anchor rod drawings, according to example embodiments. Method 300 may begin at step 302.

At step 302, server system 104 may receive an order request from user device 102. For example, in some embodiments, user device 102 may submit an order request to design system 116 using application 112. In some embodiments, the order request may include parameters associated with a target building or structure for which anchor rod drawings are being sought. Exemplary parameters may include, but are not limited to, one or more of building geometry, jobsite, specific environmental loads, governing building code, and project specific building characteristics.

At step 304, server system 104 may compare the parameters in the order request to pre-established conditions. The pre-established conditions may dictate whether the order request is suitable or compatible with an automated process for generating anchor rod drawings. In some embodiments, the conditions may include various aspects or traits of the request, such as, but not limited to addlines, multiple buildings in the order request, crane systems, fixed based bracing column bracing, and the like. In some embodiments, server system 104 may leverage complexity calculator module 121 to determine whether the parameters in the order request satisfy pre-established conditions, such as being within a threshold level of complexity.

At step 306, server system 104 may determine whether the parameters in the order request satisfy the pre-established conditions. If at step 306, server system 104 determines that the order request violates one or more pre-established conditions, then method 300 may revert to step 302. For example, server system 104 may notify user device 102 that one or more parameters in the order request violate one or more conditions. In some embodiments, server system 104 may generate a report that includes all conditions that were applied to the order request and indications regarding whether each condition was violated or satisfied. In this manner, the user of user device 102 may be able to resubmit the order request with updated parameters that might satisfy the one or more conditions.

If, however, at step 306, server system 104 determines that the order request satisfies the pre-established conditions, then method 300 may proceed to step 308. At step 308, server system 104 may generate design information for the anchor rod system based on the order request. For example, server system 104 may generate an anchor rod system design by applying one or more of applicable building codes, structural engineering principles, and steel construction and metal building specifications to the inputs of order request.

At step 310, server system 104 may generate preliminary anchor rod drawings based on the design information. For example, server system 104 may utilize one or more computer aided design programs, such as, but not limited to AutoCAD or TEKLA, to generate the preliminary anchor rod drawings.

At step 312, server system 104 may cause a sealing engineer to review and approve the preliminary drawings. For example, once server system 104 generates the preliminary anchor rod drawings, server system 104 may notify a sealing engineer that there is a new task to review. In some embodiments, server system 104 may notify a sealing engineer that was previously assigned to the user's order request. In some embodiments, server system 104 may notify a plurality of sealing engineers that a new set of preliminary anchor rod drawings are available for review and any one of the plurality of scaling engineers may access and review the preliminary anchor rod drawings. In embodiments, server system 104 may provide sealing engineer with the preliminary drawings, design information, and design reports for review.

In some embodiments, method 300 may further include step 313. At step 313, server system 104 may generate permit drawings for the order request. For example, permit drawing engine 125 may generate permit drawings based on design information the parameters in the order request and/or the approved anchor rod drawings. In some embodiments, permit drawing engine 125 may use Tekla to generate the permit drawings based on the design information and/or the approved anchor rod drawings.

At step 314, server system 104 may deliver sealing engineer approved drawings to user device 102. For example, once server system 104 receives an approval from a sealing engineer device 106, server system 104 may make the approved anchor rod drawings available to user device 102. Approved anchor rod drawings may be sufficiently detailed such that contractors may be able to use the approved anchor rod drawings to build and pour the foundation. In some embodiments, server system 104 may also deliver the permit drawings, if generated.

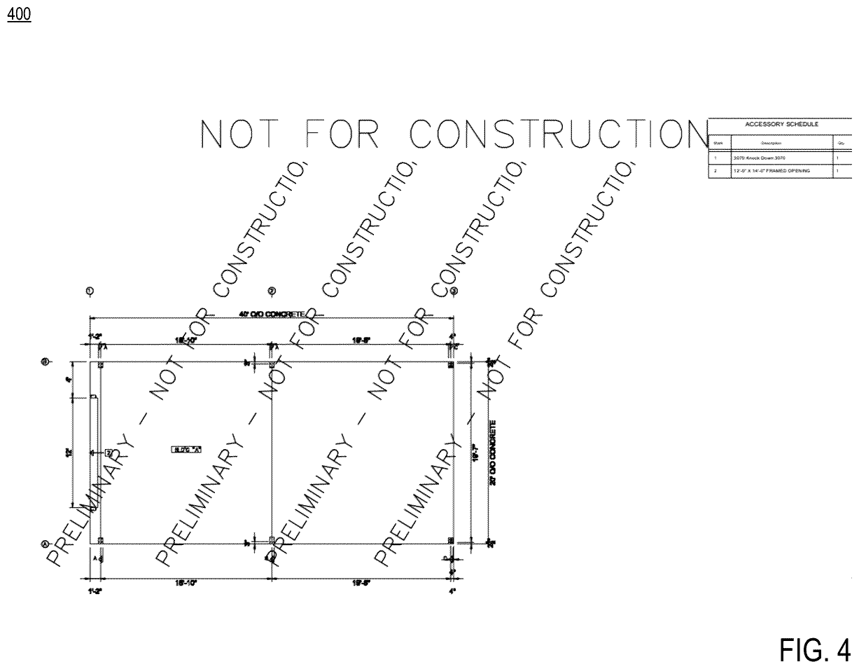

FIG. 4 illustrates a conventional anchor rod drawing 400, according to example embodiments. As shown, conventional anchor rod drawing 400 are preliminary in nature and merely assist customers in setting up their building configuration as well as providing an aid for foundation pricing. Based on conventional anchor rod drawing 400 alone, a contractor, for example, would be unable to build and pour the foundation for a target project.

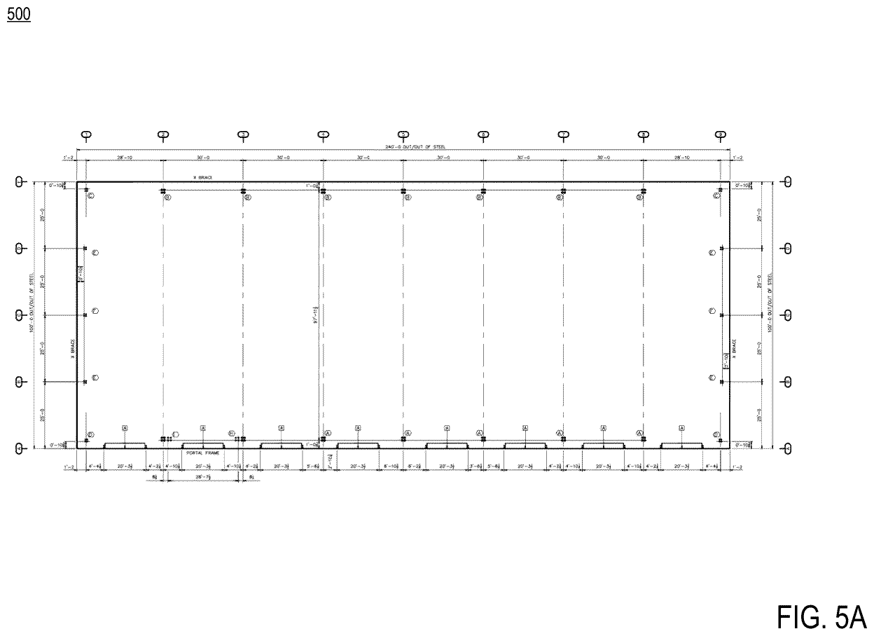

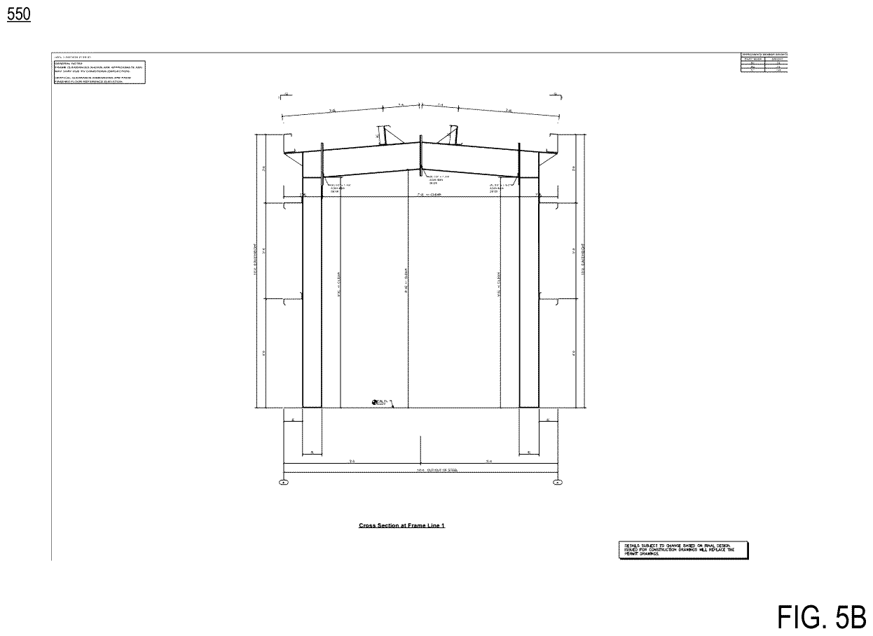

FIG. 5A illustrates an improved anchor rod drawing 500, according to example embodiments. Anchor rod drawing 500 may be representative of an anchor rod drawing generated using the foregoing automated anchor rod drawing process. As shown, improved anchor rod drawing 500 provides more detail regarding the placement and dimensions of the anchor rods within the target project.

FIG. 5B illustrates a sheet of an improved permit drawing 550, according to example embodiments. As shown, permit drawing 550 may include more detailed information beyond merely the anchor rod information provided in anchor rod drawings (e.g., anchor rod drawings 500). More generally, permit drawing 550 may include the requisite information required by local jurisdictions for obtaining a permit for a building project.

FIG. 6 illustrates an exemplary graphical user interface (GUI) 600, according to example embodiments. GUI 600 may be representative of a graphical user interface associated with application 112. AS shown, GUI 600 may provide users with a report 602. Report 602 may provide an indication of the conditions that are either satisfied or violated by the user's order request. As shown, the check marks may indicate that the user's order request satisfies the pre-determined condition; conversely, an x-mark may indicate that the user's order request violates a given pre-determined condition. In this manner, a user may adjust or update the order request to conform with the pre-determined conditions.

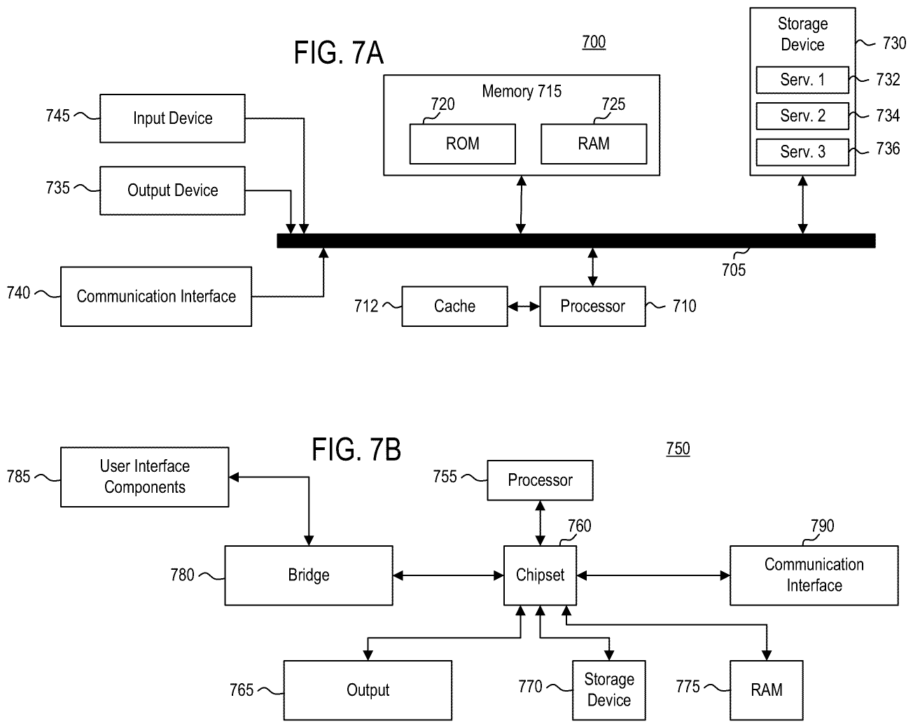

FIG. 7A illustrates an architecture of system bus computing system 700, according to example embodiments. One or more components of system 700 may be in electrical communication with each other using a bus 705. System 700 may include a processor (e.g., one or more CPUs, GPUs, or other types of processors) 710 and a system bus 705 that couples various system components including the system memory 715, such as read only memory (ROM) 720 and random access memory (RAM) 725, to processor 710. System 700 can include a cache of high-speed memory connected directly with, in close proximity to, or integrated as part of processor 710. System 700 can copy data from memory 715 and/or storage device 730 to cache 712 for quick access by processor 710. In this way, cache 712 may provide a performance boost that avoids processor 710 delays while waiting for data. These and other modules can control or be configured to control processor 710 to perform various actions. Other system memory 715 may be available for use as well. Memory 715 may include multiple different types of memory with different performance characteristics. Processor 710 may be representative of a single processor or multiple processors. Processor 710 can include one or more of a general purpose processor or a hardware module or software module, such as service 1 732, service 2 734, and service 7 736 stored in storage device 730, configured to control processor 710, as well as a special-purpose processor where software instructions are incorporated into the actual processor design. Processor 710 may essentially be a completely self-contained computing system, containing multiple cores or processors, a bus, memory controller, cache, etc. A multi-core processor may be symmetric or asymmetric.

To enable user interaction with the system 700, an input device 745 which can be any number of input mechanisms, such as a microphone for speech, a touch-sensitive screen for gesture or graphical input, keyboard, mouse, motion input, speech and so forth. An output device 735 (e.g., a display) can also be one or more of a number of output mechanisms known to those of skill in the art. In some instances, multimodal systems can enable a user to provide multiple types of input to communicate with system 700. Communications interface 740 can generally govern and manage the user input and system output. There is no restriction on operating on any particular hardware arrangement and therefore the basic features here may easily be substituted for improved hardware or firmware arrangements as they are developed.

Storage device 730 may be a non-volatile memory and can be a hard disk or other types of computer readable media that can store data that are accessible by a computer, such as magnetic cassettes, flash memory cards, solid state memory devices, digital versatile disks, cartridges, random access memories (RAMs) 725, read only memory (ROM) 720, and hybrids thereof.

Storage device 730 can include services 732, 734, and 736 for controlling the processor 710. Other hardware or software modules are contemplated. Storage device 730 can be connected to system bus 705. In one aspect, a hardware module that performs a particular function can include the software component stored in a computer-readable medium in connection with the necessary hardware components, such as processor 710, bus 705, output device 735 (e.g., a display), and so forth, to carry out the function.

FIG. 7B illustrates a computer system 750 having a chipset architecture, according to example embodiments. Computer system 750 may be an example of computer hardware, software, and firmware that can be used to implement the disclosed technology. System 750 can include one or more processors 755, representative of any number of physically and/or logically distinct resources capable of executing software, firmware, and hardware configured to perform identified computations. One or more processors 755 can communicate with a chipset 760 that can control input to and output from one or more processors 755. In this example, chipset 760 outputs information to output 765, such as a display, and can read and write information to storage device 770, which can include magnetic media, and solid-state media, for example. Chipset 760 can also read data from and write data to storage device 775 (e.g., RAM). A bridge 780 for interfacing with a variety of user interface components 785 can be provided for interfacing with chipset 760. Such user interface components 785 can include a keyboard, a microphone, touch detection and processing circuitry, a pointing device, such as a mouse, and so on. In general, inputs to system 750 can come from any of a variety of sources, machine generated and/or human generated.

Chipset 760 can also interface with one or more communication interfaces 790 that can have different physical interfaces. Such communication interfaces can include interfaces for wired and wireless local area networks, for broadband wireless networks, as well as personal area networks. Some applications of the methods for generating, displaying, and using the GUI disclosed herein can include receiving ordered datasets over the physical interface or be generated by the machine itself by one or more processors 755 analyzing data stored in storage device 770 or 775. Further, the machine can receive inputs from a user through user interface components 785 and execute appropriate functions, such as browsing functions by interpreting these inputs using one or more processors 755.

It can be appreciated that example systems 700 and 750 can have more than one processor 710 or be part of a group or cluster of computing devices networked together to provide greater processing capability.

While the foregoing is directed to embodiments described herein, other and further embodiments may be devised without departing from the basic scope thereof. For example, aspects of the present disclosure may be implemented in hardware or software or a combination of hardware and software. One embodiment described herein may be implemented as a program product for use with a computer system. The program(s) of the program product define functions of the embodiments (including the methods described herein) and can be contained on a variety of computer-readable storage media. Illustrative computer-readable storage media include, but are not limited to: (i) non-writable storage media (e.g., read-only memory (ROM) devices within a computer, such as CD-ROM disks readably by a CD-ROM drive, flash memory, ROM chips, or any type of solid-state non-volatile memory) on which information is permanently stored; and (ii) writable storage media (e.g., floppy disks within a diskette drive or hard-disk drive or any type of solid state random-access memory) on which alterable information is stored. Such computer-readable storage media, when carrying computer-readable instructions that direct the functions of the disclosed embodiments, are embodiments of the present disclosure.

It will be appreciated to those skilled in the art that the preceding examples are exemplary and not limiting. It is intended that all permutations, enhancements, equivalents, and improvements thereto are apparent to those skilled in the art upon a reading of the specification and a study of the drawings are included within the true spirit and scope of the present disclosure. It is therefore intended that the following appended claims include all such modifications, permutations, and equivalents as fall within the true spirit and scope of these teachings.

We claim:

1. A method of generating anchor rod drawings for a building project comprising:
receiving, by a computing system, an anchor rod drawing request from a user device, the anchor rod drawing request comprising parameters associated with a target structure;
determining, by the computing system, whether the anchor rod drawing request is compatible with an automated anchor rod drawing process by comparing the parameters associated with the target structure to pre-established conditions, wherein the pre-established conditions define a suitability of the anchor rod drawing request with the automated anchor rod drawing process;
based on determining that the anchor rod drawing request is compatible with the automated anchor rod drawing process, generating, by the computing system, design information for an anchor rod system based on the anchor rod drawing request by applying one or more of applicable building codes, structural engineering principles, steel construction specifications, or metal building specifications to the parameters associated with the target structure;
generating, by the computing system, preliminary anchor rod drawings based on the design information using a computer aided design program;
prompting, by the computing system, a sealing engineer to review and approve the preliminary anchor rod drawings; receiving, by the computing system, an indication that the sealing engineer has reviewed and approved the preliminary anchor rod drawings;
responsive to the indication, generating, by the computing system, permit drawings based on one or more of the approved anchor rod drawings and/or the parameters; and
delivering, by the computing system, approved anchor rod drawings and the permit drawings to the user device.

2. The method of claim 1, further comprising:
prompting, by the computing system, the sealing engineer to review and approved the permit drawings.

3. The method of claim 1, further comprising:
responsive to determining that the anchor rod drawing request violates at least one condition of the pre-established conditions, notifying the user device of the at least one condition that was violated.

4. The method of claim 3, further comprising:
receiving, by the computing system, an updated anchor rod drawing request, wherein the updated anchor rod drawing request comprises at least one new parameter.

5. The method of claim 1, wherein generating, by the computing system, the preliminary anchor rod drawings based on the design information using the computer aided design program comprises:
generating applied loads for each anchor rod.

6. The method of claim 1, wherein determining, by the computing system, whether the anchor rod drawing request is compatible with the automated anchor rod drawing process comprises:
leveraging a complexity calculator to generate an estimated complexity of constructing the target structure.

7. The method of claim 1, wherein delivering, by the computing system, the approved anchor rod drawings to the user device comprises:
delivering the design information used to generate the preliminary anchor rod drawings to the user device.

8. A system comprising:
a processor; and
a memory having programming instructions stored thereon, which, when executed by the processor, causes the system to perform operations comprising:
receiving an anchor rod drawing request from a user device, the anchor rod drawing request comprising parameters associated with a target structure;
determining whether the anchor rod drawing request is compatible with an automated anchor rod drawing process by comparing the parameters associated with the target structure to pre-established conditions, wherein the pre-established conditions define a suitability of the anchor rod drawing request with the automated anchor rod drawing process;
based on determining that the anchor rod drawing request is compatible with the automated anchor rod drawing process, generating design information for an anchor rod system based on the anchor rod drawing request by applying one or more of applicable building codes, structural engineering principles, steel construction specifications, or metal building specifications to the parameters associated with the target structure;
generating preliminary anchor rod drawings based on the design information using a computer aided design program;
prompting a sealing engineer to review and approve the preliminary anchor rod drawings;
receiving an indication that the sealing engineer has reviewed and approved the preliminary anchor rod drawings;
responsive to the indication, generating permit drawings based on one or more of approved anchor rod drawings and/or the parameters; and
delivering approved anchor rod drawings to the user device.

9. The system of claim 8, wherein the operations further comprise: prompting the sealing engineer to review and approved the permit drawings.

10. The system of claim 8, wherein the operations further comprise:
responsive to determining that the anchor rod drawing request violates at least one condition of the pre-established conditions, notifying the user device of the at least one condition that was violated.

11. The system of claim 10, wherein the operations further comprise:
receiving an updated anchor rod drawing request, wherein the updated anchor rod drawing request comprises at least one new parameter.

12. The system of claim 8, wherein generating the preliminary anchor rod drawings based on the design information using the computer aided design program comprises:
generating applied loads for each anchor rod.

13. The system of claim 8, wherein determining, by the computing system, whether the anchor rod drawing request is compatible with the automated anchor rod drawing process comprises:
leveraging a complexity calculator to generate an estimated complexity of constructing the target structure.

14. The system of claim 8, wherein delivering the approved anchor rod drawings to the user device comprises:
delivering the design information used to generate the preliminary anchor rod drawings to the user device.

15. A non-transitory computer readable medium comprising one or more sequences of instructions, which, when executed by one or more processors, causes a computing system to perform operations comprising:
receiving, by the computing system, an anchor rod drawing request from a user device, the anchor rod drawing request comprising parameters associated with a target structure;
determining, by the computing system, whether the anchor rod drawing request is compatible with an automated anchor rod drawing process by comparing the parameters associated with the target structure to pre-established conditions, wherein the pre-established conditions define a suitability of the anchor rod drawing request with the automated anchor rod drawing process;
based on determining that the anchor rod drawing request is compatible with the automated anchor rod drawing process, generating, by the computing system, design information for an anchor rod system based on the anchor rod drawing request by applying one or more of applicable building codes, structural engineering principles, steel construction specifications, or metal building specifications to the parameters associated with the target structure;
generating, by the computing system, preliminary anchor rod drawings based on the design information using a computer aided design program;
prompting, by the computing system, a sealing engineer to review and approve the preliminary anchor rod drawings;
receiving, by the computing system, an indication that the sealing engineer has reviewed and approved the preliminary anchor rod drawings;
responsive to the indication, generating, by the computing system, permit drawings based on one or more of the approved anchor rod drawings and the/or the parameters; and
delivering, by the computing system, the approved anchor rod drawings and the permit drawings to the user device.

16. The non-transitory computer readable medium of claim 15, further comprising:
prompting, by the computing system, the sealing engineer to review and approved the permit drawings.

17. The non-transitory computer readable medium of claim 15, further comprising:
responsive to determining that the anchor rod drawing request violates at least one condition of the pre-established conditions, notifying the user device of the at least one condition that was violated; and
receiving, by the computing system, an updated anchor rod drawing request, wherein the updated anchor rod drawing request comprises at least one new parameter.

18. The non-transitory computer readable medium of claim 15, wherein generating, by the computing system, the preliminary anchor rod drawings based on the design information using the computer aided design program comprises:
generating applied loads for each anchor rod.

19. The non-transitory computer readable medium of claim 15, wherein determining, by the computing system, whether the anchor rod drawing request is compatible with the automated anchor rod drawing process comprises:
leveraging a complexity calculator to generate an estimated complexity of constructing the target structure.

20. The non-transitory computer readable medium of claim 15, wherein delivering, by the computing system, the approved anchor rod drawings to the user device comprises:
delivering the design information used to generate the preliminary anchor rod drawings to the user device.
